(19) United States
(12) Patent Application Publication
(10) Pub. No.: US 2019/0203111 A1
(43) Pub. Date: Jul. 4, 2019

(54) METHOD AND DEVICE FOR EXCHANGING QUANTUM DOT LIGANDS

(71) Applicant: BOE TECHNOLOGY GROUP CO., LTD., Beijing (CN)

(72) Inventor: Wenhai MEI, Beijing (CN)

(73) Assignee: BOE TECHNOLOGY GROUP CO., LTD., Beijing (CN)

(21) Appl. No.: 16/100,011

(22) Filed: Aug. 9, 2018

(30) Foreign Application Priority Data
Jan. 3, 2018 (CN) 201810004184.7

(51) Int. Cl. C09K 11/02; C09K 11/88; H01L 51/50; H01L 33/06

(52) U.S. Cl. CPC C09K 11/02; C09K 11/88; B82Y 20/00; H01L 33/06; H01L 51/502

(57) ABSTRACT

The present disclosure provides a method and a device for exchanging quantum dot ligands. The method includes: loading, into a column tube, granular quantum dots to whose surface a first ligand is attached; passing a replacing liquid through the column tube to replace the first ligand attached to the surface of the quantum dots, so as to obtain quantum dots to whose surface a second ligand is attached; passing an eluent through the column tube to elute the quantum dots to whose surface the second ligand is attached; collecting the eluent passed through the column tube; and detecting whether the eluent passed through the column tube contains the quantum dots to whose surface the second ligand is attached, if no, repeating the above step, and if yes, quantitatively analyzing the content of the second ligand attached to the surface of the quantum dots.

### CROSS-REFERENCE TO RELATED APPLICATION

This application claims priority to Chinese Patent Application No. 201810004184.7 filed on Jan. 3, 2018, which is incorporated herein by reference in its entirety.

### TECHNICAL FIELD

The present disclosure relates to the field of nanoparticle preparation, in particular to a method and a device for exchanging quantum dot ligands.

### BACKGROUND

Quantum dots (QDs) are zero-dimensional semiconductor nanocrystals that are approximately spherical, have diameters of 1 to 12 nm, and may be dispersed in water or organic solvents to form a colloid. The size of the quantum dots is close to or even smaller than the Bohr radius of the exciton (i.e. electron hole pair) of the corresponding semiconductor bulk phase material. Electrons and holes generated during the excitation are confined to a narrow three-dimensional space, and thus they exhibit quantum confinement effect and have unique optical properties.

A quantum dot light emitting diode display (QLED) is a new type of display technology developed based on an organic light emitting display (OLED). The difference between the two is that the light emitting layer in the QLED is a quantum dot layer, the principle of which is shown as follows: electrons/holes are injected into a quantum dot layer through an electron/hole transport layer, and the electrons and holes combines in the quantum dot layer to emit light. As compared with OLED devices, QLED has advantages such as narrow emission peak, high color saturation, and wide color gamut.

### SUMMARY

The technical problem to be solved by the present disclosure is to provide a method and a device for exchanging quantum dot ligands.

One embodiment of the present disclosure provides a method for exchanging quantum dot ligands, which includes the following steps:

step S 1, loading, into a column tube, granular quantum dots to whose surface a first ligand is attached;

step S2, passing a replacing liquid through the column tube to replace the first ligand attached to the surface of the quantum dots, so as to obtain quantum dots to whose surface a second ligand is attached, in which the replacing liquid comprises a poor solvent for the quantum dots to whose surface the first ligand is attached and the second ligand dissolved in the replacing liquid;

step S3, passing an eluent through the column tube to elute the quantum dots to whose surface the second ligand is attached, in which the eluent is a mixture of a good solvent and a poor solvent for the quantum dots to whose surface the second ligand is attached;

step S4, collecting the eluent passed through the column tube; and

step S5, detecting whether the eluent passed through the column tube contains the quantum dots to whose surface the second ligand is attached, and if no, returning to perform step S2, if yes, quantitatively analyzing a content of the second ligand attached to the surface of the quantum dots.

Optionally, the Method Further Includes:

judging whether the content of the second ligand attached to the surface of the quantum dots quantitatively analyzed in step S5 reaches a target content;

if no, returning to perform step S2, and adjusting a ratio of the good solvent to the poor solvent for the quantum dots to whose surface the second ligand is attached in the eluent at every performing of step S3;

if yes, ending.

Optionally, the second ligand is a polar ligand.

Optionally, the adjusting includes adjusting a content of the good solvent for the quantum dots to whose surface the second ligand is attached in the eluent at an Nth performing of the step S3 to be less than a content of the good solvent for the quantum dots to whose surface the second ligand is attached in the eluent at an N+1th performing of the step S3, in which N is a positive integer.

Optionally, the first ligand is oleic acid, oleylamine, trioctylphosphine, or trioctylphosphine oxide.

Optionally, the quantum dots are made from CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, or CsPhI₃/ZnS.

Optionally, a flow rate of the replacing liquid passing through the column tube is 1 to 5 cm/min.

Optionally, a concentration of the second ligand in the replacing liquid is 10 mg/mL to 20 mg/mL.

Optionally, the poor solvent for the quantum dots to whose surface the first ligand is attached in the replacing liquid is dimethylformamide, dimethylacetamide, dimethylsulfoxide or N-methylpyrrolidone.

Optionally, a volume ratio of the good solvent to the poor solvent for the quantum dots to whose surface the second ligand is attached in the eluent is 0.1:1 to 10:1.

Optionally, the second ligand is mercaptoethanol, mercaptohexanol, propanethiol, propanedithiol, 2-mercapto-3-butanol or 6-mercaptohexanol.

Optionally, the good solvent for the quantum dots to whose surface the second ligand is attached is C6 to C16 alkane, toluene or chlorobenzene.

Optionally, the poor solvent for the quantum dots to whose surface the second ligand is attached is dimethylformamide, dimethylacetamide, dimethylsulfoxide or N-methylpyrrolidone.

A further embodiment of the present disclosure provides an device for exchanging quantum dot ligands, which includes:

a column tube, filled with granular quantum dots to whose surface a first ligand is attached;

a replacing liquid tank communicated with a top of the column tube through a first pipeline and filled with a replacing liquid, in which the replacing liquid comprises a poor solvent for the quantum dots to whose surface the first ligand is attached and a second ligand dissolved in the replacing liquid;

an eluent tank communicated with the top of the column tube through a second pipeline and filled with an eluent, in which the eluent is a mixture of a good solvent and a poor solvent for the quantum dots to whose surface the second ligand is attached; and

a collection tank communicated with a bottom of the column tube through a third pipeline.

Optionally, both the first pipeline and the second pipeline are provided with a valve.

Optionally, the device further includes a pressure pump connected to the first pipeline, for passing the replacing liquid through the column tube at a predetermined flow rate.

### BRIEF DESCRIPTION OF THE DRAWINGS

FIG. 1 shows a flow chart of a method for exchanging quantum dot ligands according to an example of the present disclosure.

FIG. 2 shows a schematic view of steps S2 and S3 according to an example of the present disclosure.

FIG. 3 shows a flow chart of a method for exchanging quantum dot ligands according to another example of the present disclosure.

FIG. 4 shows a schematic view of steps S2 and S3 according to another example of the present disclosure.

FIG. 5 shows a device for exchanging quantum dot ligands according to an example of the present disclosure.

### DETAILED DESCRIPTION

In order to better understand the present disclosure, the preferred embodiments of the present disclosure will be described below in combination with examples, but it should be understood that these descriptions are merely used to further illustrate the features and advantages of the present disclosure and are not intended to limit the present disclosure.

In the synthesis process of quantum dots used in the preparation of QLED devices of the related art, oily ligands having long chains are often used, which is beneficial to the stability of the quantum dots in the synthesis system. However, long-chain oil-soluble ligands can adversely affect the subsequent use of quantum dots. In QLED, ligands having long chains have insulating properties, which impede the transmission performance of carriers. In biosensors, oil-soluble ligands are adverse to the solubility of quantum dots in hydrophilic systems. Overall, the specific design for ligands is of great significance to the development in performance of quantum dots.

In the studies of the related art, the ligand attached to the surface of the quantum dots may be changed by a ligand exchange method. Ligand exchange generally adopts two manners. The first manner is to dissolve the prepared quantum dots in a suitable solvent and add new ligands to carry out a homogeneous ligand exchange. However, the disadvantage of this manner lies in that the quantum dots obtained after the ligand exchange are unstable, and they are prone to coagulation in the solution. The second manner is to prepare the quantum dots as a thin film in the device, and immerse the thin film in a solution dissolved with a new ligand. This exchange manner may cause some damage to other layers.

In view of the above, embodiments of the present disclosure provides a method and a device for exchanging quantum dot ligands.

The poor solvent referred to in the present disclosure means that its solubility to the quantum dots is less than 1 mg/mL, while the good solvent means that its solubility to the quantum dots is higher than 10 mg/mL.

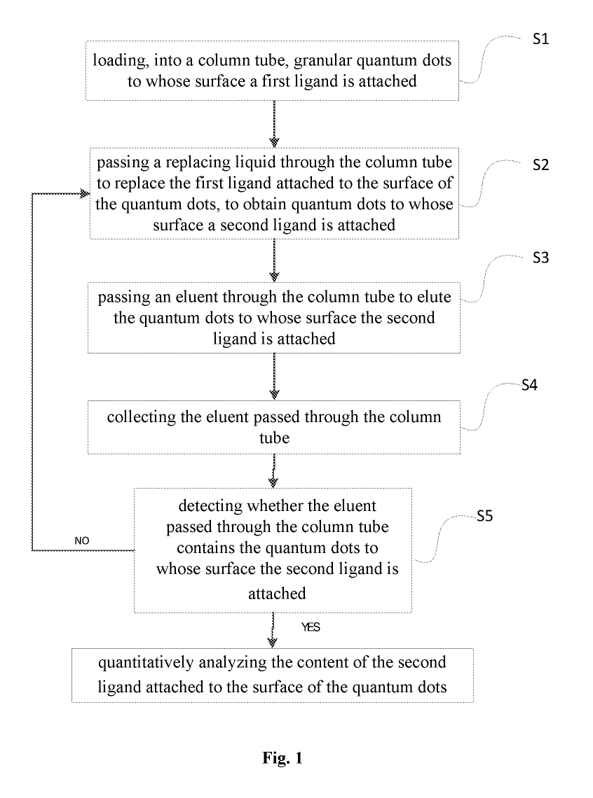

Referring to FIG. 1, an example of the present disclosure provide a method for exchanging quantum dot ligands, which includes the following steps:

step S1, loading, into a column tube, granular quantum dots to whose surface a first ligand is attached;

step S2, passing a replacing liquid through the column tube to replace the first ligand attached to the surface of the quantum dots, so as to obtain quantum dots to whose surface a second ligand is attached, in which the replacing liquid comprises a poor solvent for the quantum dots to whose surface the first ligand is attached and the second ligand dissolved in the replacing liquid;

step S3, passing an eluent through the column tube to elute the quantum dots to whose surface the second ligand is attached, in which the eluent is a mixture of a good solvent and a poor solvent for the quantum dots to whose surface the second ligand is attached;

step S4, collecting the eluent passed through the column tube; and

step S5, detecting whether the eluent passed through the column tube contains the quantum dots to whose surface the second ligand is attached, and if no, returning to perform step S2,

if yes, quantitatively analyzing the content of the second ligand attached to the surface of the quantum dots.

According to an example of the present disclosure, the method for exchanging quantum dot ligands is described in detail as follows.

In step S1, granular quantum dots to whose surface a first ligand is attached are loaded into a column tube.

The first ligand is the original ligand on the surface of the quantum dots, and in some examples maybe oleic acid, oleylamine, trioctylphosphine, or trioctylphosphine oxide.

The quantum dots may be made from CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, or CsPhI₃/ZnS.

The source of the quantum dots is not particularly limited, and the quantum dots may be prepared by a high temperature oil phase method or purchased commercially. The quantum dots to whose surface the first ligand is attached may be solid and granular, and are optionally densely packed during being loaded into the column tube.

In step S2, a replacing liquid is passed through the column tube to replace the first ligand attached to the surface of the quantum dots, so as to obtain quantum dots to whose surface a second ligand is attached, in which the replacing liquid comprises a poor solvent for the quantum dots to whose surface the first ligand is attached and the second ligand dissolved in the replacing liquid.

In an example, the second ligand may be a polar ligand. Optionally, the ligand is mercaptoethanol, mercaptohexanol, propanethiol, propanedithiol, 2-mercapto-3-butanol or 6-mercaptohexanol.

Optionally, the concentration of the second ligand in the replacing liquid is 10 mg/mL to 20 mg/mL.

Optionally, the flow rate of the replacing liquid passing through the column tube is 1 to 5 cm/min.

The poor solvent for the quantum dots to whose surface the first ligand is attached may be dimethylformamide, dimethylacetamide, dimethylsulfoxide or N-methylpyrrolidone.

In this step, the second ligand dissolved in the replacing liquid replaces the first ligand attached to the surface of the quantum dots, and the content of the second ligand attached to the surface of the quantum dots varies depending on different degrees of the replacement.

In step S3, an eluent is passed through the column tube to elute the quantum dots to whose surface the second ligand is attached, in which the eluent is a mixture of a good solvent and a poor solvent for the quantum dots to whose surface the second ligand is attached.

The good solvent for the quantum dots to whose surface the second ligand is attached may be C6 to C16 alkane, toluene or chlorobenzene, and preferably hexane, heptane, tetradecane, or hexadecane.

The poor solvent for the quantum dots to whose surface the second ligand is attached may be dimethylformamide, dimethylacetamide, dimethylsulfoxide or N-methylpyrrolidone.

The volume ratio of the good solvent to the poor solvent for the quantum dots to whose surface the second ligand is attached in the eluent may be 0.1:1 to 10:1.

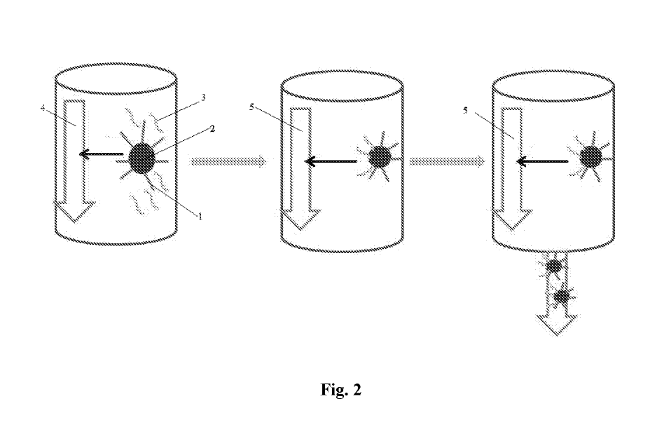

In steps S2 and S3 as shown in FIG. 2, 1 represents a first ligand, 2 represents quantum dots, 3 represents a second ligand, 4 represents a replacing liquid, and 5 represents an eluent. The second ligand partially replaces the first ligand attached to the surface of the quantum dots, and the quantum dots attached with the second ligand are eluted with the eluent.

In step S4, the eluent passed through the column tube is collected.

This step collects the eluent passed through the column tube.

In step S5, it is detected whether the eluent passed through the column tube contains the quantum dots to whose surface the second ligand is attached. The detection may adopt UV detection.

If the eluent passed through the column tube does not contain the quantum dots to whose surface the second ligand is attached, it indicates that the second ligand fails to replace the first ligand, or a replacement error occurs, or the second ligand fails to be eluted, thus the method returns to step S2.

If the eluent passed through the column tube contains the quantum dots to whose surface the second ligand is attached, the content of the second ligand attached to the surface of the quantum dots is quantitatively analyzed. The quantitative analysis may adopt nuclear magnetic resonance detection.

The method for exchanging the quantum dot ligand according to the examples of the present disclosure may not only obtain stable quantum dots, but also quantify the new ligand on the surface of the quantum dots and realize an effective exchange of the original ligand on the surface of the quantum dots.

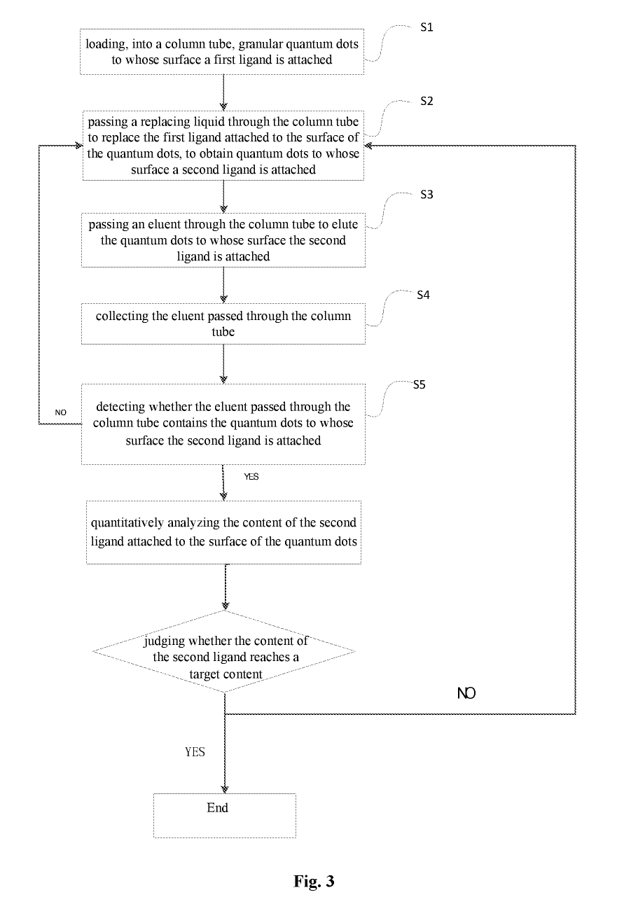

According to the present disclosure, referring to FIG. 3, a method for exchanging according to another example is described in detail as follows:

step S1, loading, into a column tube, granular quantum dots to whose surface a first ligand is attached;

step S2, passing a replacing liquid through the column tube to replace the first ligand attached to the surface of the quantum dots, so as to obtain quantum dots to whose surface a second ligand is attached, in which the replacing liquid comprises a poor solvent for the quantum dots to whose surface the first ligand is attached and the second ligand dissolved in the replacing liquid;

step S3, passing an eluent through the column tube to elute the quantum dots to whose surface the second ligand is attached, in which the eluent is a mixture of a good solvent and a poor solvent for the quantum dots to whose surface the second ligand is attached;

step S4, collecting the eluent passed through the column tube; and

step S5, detecting whether the eluent passed through the column tube contains the quantum dots to whose surface the second ligand is attached, and if the eluent passed through the column tube does not contain the quantum dots to whose surface the second ligand is attached, returning to perform step S2;

if the eluent passed through the column tube contains the quantum dots to whose surface the second ligand is attached, quantitatively analyzing the content of the second ligand attached to the surface of the quantum dots.

Optionally, judging is performed based on the content of the second ligand attached to the surface of the quantum dots quantitatively analyzed in step S5, and if the content of the second ligand does not reach the target value, the method returns to step S2. In each performing of step S3, the ratio of the good solvent to the poor solvent in the eluent is adjusted accordingly.

Optionally, the ratio of the good solvent to the poor solvent in the eluent in the Mth performing of step S3 is adjusted according to the content of the second ligand attached to the surface of the quantum dots obtained by quantitative analysis in M−1th performing of step S5. M is a positive integer greater than two.

If the content of the second ligand reaches the target value, the method ends.

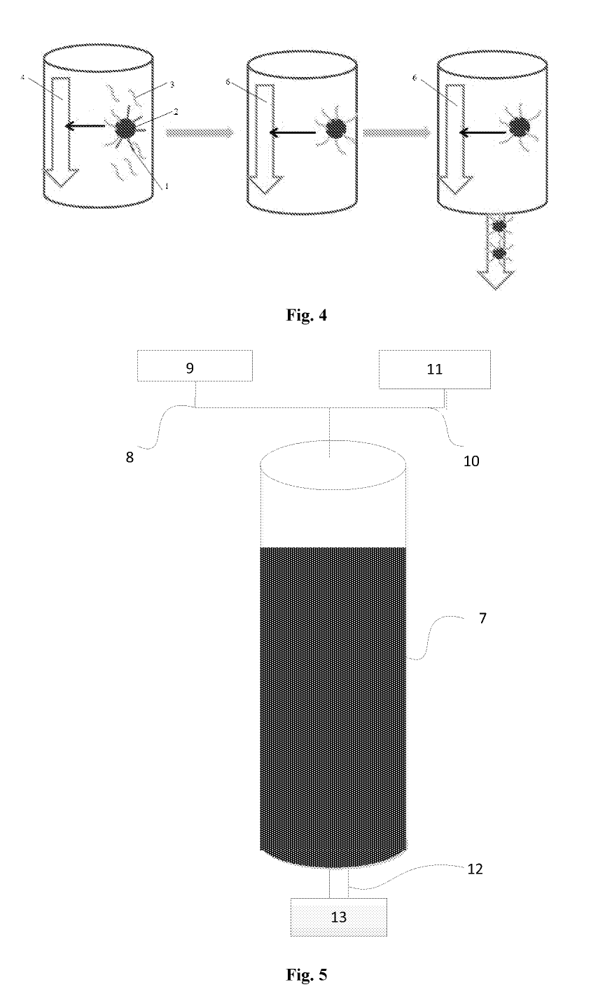

Steps S2 and S3 are repeated, as shown in FIG. 4, in which 1 represents a first ligand, 2 represents quantum dots, 3 represents a second ligand, 4 represents a replacing liquid, and 6 represents an eluent after adjustment. The second ligand gradually replaces all the first ligands on the surface of the quantum dots, and the quantum dots to whose surface the second ligand is attached are eluted.

When the second ligand is a polar ligand, the content of the second ligand on the surface of the quantum dots is increased by each replacement of the first ligand with the second ligand. The polarity of the quantum dots to whose surface the second ligand is attached gradually increases, and the dissolution performance also changes. Therefore, the ratio of the good solvent to the poor solvent in the elution must be adjusted in order to elute the quantum dots to whose surface various content of the second ligands is attached.

Optionally, the ratio of the good solvent is gradually increased when adjusting the ratio of the good solvent to the poor solvent in the elution. That is, the content of the good solvent for the quantum dots to whose surface the second ligand is attached in the eluent at the Nth performing of the step S3 is adjusted to be less than the content of the good solvent for the quantum dots to whose surface the second ligand is attached in the eluent at the N+1th performing of the step S3, in which N is a positive integer.

The exchanging method according to examples of the present disclosure may effectively replace the first ligand with the second ligand without affecting the stability of the quantum dots as such, and may quantify the second ligands on the surface of the quantum dots. Further, the processes of exchange and elution are repeated so as to achieve effective and quantitative exchange of the original ligands on the surface of the quantum dots.

Another example of the present disclosure provides an device for exchanging quantum dot ligands, referring to FIG. 5, which includes:

a column tube 7, filled with granular quantum dots to whose surface a first ligand is attached;

a replacing liquid tank 9 communicated with the top of the column tube 7 through a first pipeline 8 and filled with a replacing liquid, in which the replacing liquid comprises a poor solvent for the quantum dots to whose surface the first ligand is attached and a second ligand dissolved in the replacing liquid;

an eluent tank 11 communicated with the top of the column tube 7 through a second pipeline 10 and filled with an eluent, in which the eluent is a mixture of a good solvent and a poor solvent for the quantum dots to whose surface the second ligand is attached; and

a collection tank 13 communicated with the bottom of the column tube 7 through a third pipeline 12.

Optionally, both the first pipeline 8 and the second pipeline 10 are provided with a valve.

Optionally, the first pipeline 8 is also connected with a pressure pump, such that the replacing liquid is allowed to pass through the column tube at a predetermined flow rate.

Optionally, the third pipeline 12 is provided with a valve.

As compare with the related art, the method for exchanging quantum dot ligands according to the present disclosure first utilizes quantum dots to whose surface the first ligand is attached to fill a column tube; then passes the replacing liquid containing the second ligand through the column tube, to replace the first ligand on the surface of quantum dots with the second ligand, such that the second ligand is attached to the surface of the quantum dots and the first ligand is detached from the surface of the quantum dots; and then the quantum dots to whose surface the second ligand is attached is eluted by the eluent, to obtain a stable solution of quantum dots to whose surface the second ligand is attached without coagulation. If quantum dot to whose surface a second ligand is attached is not detected in the eluent after the elution, the processes of replacement and elution are repeated until the quantum dots to whose surface the second ligand is attached can be detected and quantified.

In order to further understand the present disclosure, the method and the device for exchanging quantum dot ligands provided by the present disclosure will be described in detail in the following examples, but the protection scope of the present disclosure is not limited by the following examples.

### EXAMPLE 1

In step 1, CdSe/ZnS was prepared by a high temperature oil phase method, in which the first ligand on the surface was oleic acid. CdSe/ZnS to whose surface oleic acid was attached was precipitated from the reaction solution, washed to remove impurities, and dried to obtain CdSe/ZnS solid particles to whose surface oleic acid was attached. The CdSe/ZnS solid particles to whose surface oleic acid was attached were filled into a column tube and densely packed.

In step 2, the second ligand, mercaptoethanol, was dissolved in dimethylformamide (DMF) at a concentration of 15 mg/ml, to form a replacing liquid. The replacing liquid was poured from the upper end of the column tube, and the eluent was passed through a column of dense packed CdSe/ZnS solid particles to whose surface oleic acid was attached at a flow rate of 5 cm/min under a certain pressure.

In step 3, an eluent, in which DMF : n-hexane=10: 1, was then injected into the device for elution.

In step 4, the eluent passed through the column tube was collected.

In step 5, the eluent passed through the column tube was detected to learn that the eluent contains the quantum dots to whose surface the second ligand was attached; and the second ligand on the surface of the quantum dots eluted was quantitatively analyzed by nuclear magnetic resonance method, and the value of exchange degree was 7% to 8%. In example 1, the target value of the exchange degree was set to 69%. In the context of the present disclosure, the numerical value of the exchange degree was defined as the percentage of the first ligand attached to the surface of the quantum dots replaced by the second ligand.

Steps 2 to 5 were repeated.

The replacing liquid was passed through the column of dense packed CdSe/ZnS solid particles to whose surface oleic acid was attached at a flow rate of 5 cm/min. Afterwards, an eluent, in which DMF : n-hexane=5: 1, was then injected into the device for elution. The eluent passed through the column tube was received at the lower end of the column tube.

The second ligand on the surface of the quantum dots eluted was quantitatively analyzed by nuclear magnetic resonance method, and the value of exchange degree was 16% to 17%.

Steps 2 to 5 were repeated.

The replacing liquid was passed through the column of dense packed CdSe/ZnS solid particles to whose surface oleic acid was attached at a flow rate of 5 cm/min. Afterwards, an eluent, in which DMF : n-hexane=1: 1, was then injected into the device for elution. The eluent passed through the column tube was received at the lower end of the column tube.

The second ligand on the surface of the quantum dots eluted was quantitatively analyzed by nuclear magnetic resonance method, and the value of exchange degree was 36% to 67%.

Steps 2 to 5 were repeated.

The replacing liquid was passed through the column of dense packed CdSe/ZnS solid particles to whose surface oleic acid was attached at a flow rate of 5 cm/min. Afterwards, an eluent, in which DMF : n-hexane=1: 2, was then injected into the device for elution. The eluent passed through the column tube was received at the lower end of the column tube.

The second ligand on the surface of the quantum dots eluted was quantitatively analyzed by nuclear magnetic resonance method, and the value of exchange degree was 51% to 52%.

Steps 2 to 5 were repeated.

The replacing liquid was passed through the column of dense packed CdSe/ZnS solid particles to whose surface oleic acid was attached at a flow rate of 5 cm/min. Afterwards, an eluent, in which DMF : n-hexane=1 : 5, was then injected into the device for elution. The eluent passed through the column tube was received at the lower end of the column tube.

The second ligand on the surface of the quantum dots eluted was quantitatively analyzed by nuclear magnetic resonance method, and the value of exchange degree was 69% to 72%.

Correspondences in example 1 are shown in Table 1.

TABLE 1

| | Replacement and elution were repeated. | | | | |
|---|---|---|---|---|---|
| | | Two | Three | Four | Five |
| | First | consecutive | consecutive | consecutive | consecutive |
| | performing of | performings of | performings of | performings of | performings of |
| | replacement | replacement | replacement | replacement | replacement |
| | and elution, in | and elution, in | and elution, in | and elution, in | and elution, in |
| | which DMF: | which DMF: | which DMF: | which DMF: | which DMF: |
| | n-hexane in | n-hexane in the | n-hexane in the | n-hexane in the | n-hexane in the |
| | the eluent is | second eluent is | third eluent is | fourth eluent is | fifth eluent is |
| | 10:1. | 5:1. | 1:1. | 1:2. | 1:5. |
| The | 7% to 8% | 16% to 17% | 36% to 37% | 51% to 52% | 69% to 72% |
| exchange | | | | | |
| degree of the | | | | | |
| second | | | | | |
| ligand. | | | | | |

The description of the above examples is merely used for helping to understand the method according to the present disclosure and its core idea. It should be noted that one skilled in the art would make several improvements and modifications to the present disclosure without departing from the principles of the present disclosure, and these improvements and modifications should also be regarded as falling into the protection scope of the present disclosure.

The above description of the disclosed examples allows one skilled in the art to implement or use the present disclosure. Various modifications to these examples would be apparent to one skilled in the art, and the general principles defined herein may be applied to other examples without departing from the spirit or scope of the present disclosure. Therefore, the present disclosure will not be limited to the Examples shown herein, but should conform to the widest scope consistent with the principles and novel features disclosed herein.

What is claimed is:

1. A method for exchanging quantum dot ligands, comprising the following steps:
step S1, loading, into a column tube, granular quantum dots to whose surface a first ligand is attached;
step S2, passing a replacing liquid through the column tube to replace the first ligand attached to the surface of the quantum dots, to obtain quantum dots to whose surface a second ligand is attached, wherein the replacing liquid comprises a poor solvent for the quantum dots to whose surface the first ligand is attached and the second ligand dissolved in the replacing liquid;
step S3, passing an eluent through the column tube to elute the quantum dots to whose surface the second ligand is attached, wherein the eluent is a mixture of a good solvent and a poor solvent for the quantum dots to whose surface the second ligand is attached;
step S4, collecting the eluent passed through the column tube; and
step S5, detecting whether the eluent passed through the column tube contains the quantum dots to whose surface the second ligand is attached, and if no, returning to perform step S2, if yes, quantitatively analyzing a content of the second ligand attached to the surface of the quantum dots.

2. The method according to claim 1, further comprising:
judging whether the content of the second ligand attached to the surface of the quantum dots quantitatively analyzed in step S5 reaches a target content;
if no, returning to perform step S2, and adjusting a ratio of the good solvent to the poor solvent for the quantum dots to whose surface the second ligand is attached in the eluent at every performing of step S3;
if yes, ending.

3. The method according to claim 1, wherein the second ligand is a polar ligand.

4. The method according to claim 2, wherein the second ligand is a polar ligand.

5. The method according to claim 4, wherein the adjusting comprises adjusting a content of the good solvent for the quantum dots to whose surface the second ligand is attached in the eluent at an Nth performing of the step S3 to be less than a content of the good solvent for the quantum dots to whose surface the second ligand is attached in the eluent at an N+1th performing of the step S3, and N is a positive integer.

6. The method according to claim 1, wherein the first ligand is oleic acid, oleylamine, trioctylphosphine, or trioctylphosphine oxide.

7. The method according to claim 1, wherein the quantum dots are made from CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, or CsPhI₃/ZnS.

8. The method according to claim 1, wherein a flow rate of the replacing liquid passing through the column tube is 1 to 5 cm/min.

9. The method according to claim 1, wherein a concentration of the second ligand in the replacing liquid is 10 mg/mL to 20 mg/mL.

10. The method according to claim 1, wherein the poor solvent for the quantum dots to whose surface the first ligand is attached in the replacing liquid is dimethylformamide, dimethylacetamide, dimethylsulfoxide or N-methylpyrrolidone.

11. The method according to claim 1, wherein a volume ratio of the good solvent to the poor solvent for the quantum dots to whose surface the second ligand is attached in the eluent is 0.1:1 to 10:1.

12. The method according to claim 2, wherein a volume ratio of the good solvent to the poor solvent for the quantum dots to whose surface the second ligand is attached in the eluent is 0.1:1 to 10:1.

13. The method according to claim 3, wherein the second ligand is mercaptoethanol, mercaptohexanol, propanethiol, propanedithiol, 2-mercapto-3-butanol or 6-mercaptohexanol.

14. The method according to claim 1, wherein the good solvent for the quantum dots to whose surface the second ligand is attached is C6 to C16 alkane, toluene or chlorobenzene.

15. The method according to claim 1, wherein the poor solvent for the quantum dots to whose surface the second ligand is attached is dimethylformamide, dimethylacetamide, dimethylsulfoxide or N-methylpyrrolidone.

16. A device for exchanging quantum dot ligands, comprising:
a column tube, filled with granular quantum dots to whose surface a first ligand is attached;
a replacing liquid tank communicated with a top of the column tube through a first pipeline and filled with a replacing liquid, wherein the replacing liquid comprises a poor solvent for the quantum dots to whose surface the first ligand is attached and a second ligand dissolved in the replacing liquid;
an eluent tank communicated with the top of the column tube through a second pipeline and filled with an eluent, wherein the eluent is a mixture of a good solvent and a poor solvent for the quantum dots to whose surface the second ligand is attached; and
a collection tank communicated with a bottom of the column tube through a third pipeline.

17. The device according to claim 16, wherein both the first pipeline and the second pipeline are provided with a valve.

18. The device according to claim 16, further comprising a pressure pump connected to the first pipeline, for passing the replacing liquid through the column tube at a predetermined flow rate.

19. The device according to claim 16, wherein the quantum dots are made from CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, or CsPhI₃/ZnS;
the first ligand is oleic acid, oleylamine, trioctylphosphine, or trioctylphosphine oxide; and
the second ligand is mercaptoethanol, mercaptohexanol, propanethiol, propanedithiol, 2-mercapto-3-butanol or 6-mercaptohexanol.

20. The device according to claim 16, wherein in the replacing liquid, the poor solvent for the quantum dots to whose surface the first ligand is attached is dimethylformamide, dimethylacetamide, dimethyl sul foxide or N-methylpyrrolidone; and
in the eluent, the good solvent for the quantum dots to whose surface the second ligand is attached is C6 to C16 alkane, toluene or chlorobenzene; and the poor solvent for the quantum dots to whose surface the second ligand is attached is dimethylformamide, dimethylacetamide, dimethyl sul foxide or N-methylpyrrolidone.
